(19) United States
(12) Patent Application Publication
(10) Pub. No.: US 2025/0048756 A1
(43) Pub. Date: Feb. 6, 2025

(54) PHOTO DETECTION SUBSTRATE, IMAGE SENSOR, AND ELECTRONIC APPARATUS

(71) Applicant: BOE TECHNOLOGY GROUP CO., LTD., Beijing (CN)

(72) Inventors: Rui HUANG, Beijing (CN); Jie HUANG, Beijing (CN); Jinchao ZHANG, Beijing (CN); Yunping DI, Beijing (CN); Wei YANG, Beijing (CN); Binbin TONG, Beijing (CN)

(21) Appl. No.: 18/280,731

(22) PCT Filed: Feb. 28, 2023
(86) PCT No.: PCT/CN2023/078825

§ 371 Date: Sep. 7, 2023

(51) Int. Cl. H01L 27/146

(52) U.S. Cl. CPC H01L 27/14603; H01L 27/14616; H01L 27/14636; H01L 27/14643; H01L 27/14689; H01L 27/14692

(57) ABSTRACT

A photo detection substrate, including: a base substrate; and a plurality of detection pixel units on the base substrate, where each detection pixel unit includes a signal reading circuit and a photoelectric conversion structure; the signal reading circuit includes at least one transistor each including a gate and an active layer pattern, the active layer pattern includes a channel region and a source/drain doped region; at least one transistor in the signal reading circuit is a superposed transistor on a side of the photoelectric conversion structure away from the base substrate, an orthographic projection of the active layer pattern of the superposed transistor on the base substrate overlaps an orthographic projection of the photoelectric conversion structure in the same detection pixel unit on the base substrate, and a material of the gate of the superposed transistor includes a transparent conductive material.

### TECHNICAL FIELD

The present disclosure relates to the field of display technology, and in particular to a photo detection substrate, an image sensor, and an electronic apparatus.

### BACKGROUND

An Active Pixel Sensor (APS) is characterized in that a thin film transistor and a photodiode are combined to form a pixel unit. Compared with a conventional Passive Pixel Sensor (PPS), the APS has the advantages of low noise, high reading speed, and the like, and has been widely applied to glass-based image sensors.

### SUMMARY

In a first aspect, an embodiment of the present disclosure provides a photo detection substrate, including:
a base substrate; and
a plurality of detection pixel units on the base substrate, where each of the plurality of detection pixel units includes a signal reading circuit and a photoelectric conversion structure,
where the signal reading circuit includes at least one transistor, each of the at least one transistor includes a gate and an active layer pattern, and the active layer pattern includes a channel region and a source/drain doped region; and
at least one of the at least one transistor in the signal reading circuit is a superposed transistor on a side of the photoelectric conversion structure away from the base substrate, an orthographic projection of the active layer pattern of the superposed transistor on the base substrate overlaps an orthographic projection of the photoelectric conversion structure in the same detection pixel unit on the base substrate, and a material of the gate of the superposed transistor includes a transparent conductive material.

In some embodiments, a material of the active layer pattern of the superposed transistor includes an oxide semiconductor material doped with a rare earth element.

In some embodiments, the orthographic projection of the active layer pattern of the superposed transistor on the base substrate is within the orthographic projection of the photoelectric conversion structure in the same detection pixel unit on the base substrate.

In some embodiments, the photo detection substrate further includes a plurality of gate lines sequentially arranged along a first direction and a plurality of signal reading lines sequentially arranged along a second direction, where the plurality of gate lines each extend along the second direction, the plurality of signal reading lines each extend along the first direction, and the first direction and the second direction intersect each other;
the plurality of gate lines and the plurality of signal reading lines define the plurality of detection pixel units, and the signal reading circuit in each of the plurality of detection pixel units is connected to a corresponding one of the plurality of gate lines and a corresponding one of the plurality of signal reading lines;
the photo detection substrate further includes a plurality of bias voltage supply lines; and
the photoelectric conversion structure includes a first electrode, a photoelectric conversion layer and a second electrode, the first electrode is connected to a corresponding one of the signal reading circuits, and the second electrode is connected to a corresponding one of the plurality of bias voltage supply lines.

In some embodiments, the photo detection substrate further includes:
a circuit connection pattern layer on a side of the superposed transistor away from the base substrate, where the circuit connection pattern layer includes a plurality of circuit connection patterns, and each of the plurality of circuit connection patterns is connected to the source/drain doped region of a corresponding transistor.

In some embodiments, the signal reading line is on a side of the circuit connection pattern layer away from the base substrate; and
the circuit connection pattern layer includes a first circuit connection pattern; and the signal reading line is connected to the source/drain doped region of a transistor in the signal reading circuit through the first circuit connection pattern corresponding to the transistor.

In some embodiments, a material of the circuit connection pattern layer includes a transparent conductive material.

In some embodiments, the first electrode, the bias voltage supply line, and the gate line are in the same layer.

In some embodiments, the photo detection substrate further includes a bias transmission pattern, where the second electrode of the photoelectric conversion structure is connected to the corresponding bias voltage supply line through the bias transmission pattern; and
the bias transmission pattern is arranged in the same layer as the gate of the superposed transistor.

In some embodiments, the signal reading circuit includes a switching transistor;
the gate of the switching transistor is connected to the corresponding gate line, a first pole of the switching transistor is connected to the first electrode of the photoelectric conversion structure, and a second pole of the switching transistor is connected to the corresponding signal reading line; and
the switching transistor is the superposed transistor.

In some embodiments, the bias voltage supply line is in the same layer as the gate line, and the signal reading line extends in the second direction; and
one of the bias voltage supply lines and one of the gate lines corresponding to the detection pixel unit are on two opposite sides of the photoelectric conversion structure in the detection pixel unit in the first direction, respectively.

In some embodiments, the second electrode has a third edge and a fourth edge opposite to each other in the first direction;
the gate line corresponding to the detection pixel unit is on a side closer to the fourth edge of the second electrode in the detection pixel unit, and an orthographic projection of the gate of the switching transistor on a plane, where the second electrode is located, intersects the fourth edge;
the bias voltage supply line corresponding to the detection pixel unit is on a side closer to the third edge of the second electrode in the detection pixel unit; and
the photo detection substrate further includes a bias voltage transmission pattern, the second electrode of the photoelectric conversion structure is connected to the corresponding bias voltage supply line through the bias voltage transmission pattern, the bias voltage transmission pattern is in the same layer as the gate of the superposed transistor, and an orthographic projection of the bias voltage transmission pattern on the plane, where the second electrode is located, intersects the third edge.

In some embodiments, the second electrode further has a first edge and a second edge opposite to each other in the second direction;
the photo detection substrate further includes a wiring layer on a side of the superposed transistor away from the base substrate, and the wiring layer includes the signal reading line;
one of the signal reading lines corresponding to the detection pixel unit is on a side closer to the first edge of the second electrode in the detection pixel unit;
the photo detection substrate further includes a circuit connection pattern layer between the superposed transistor and the wiring layer, the circuit connection pattern layer includes a first circuit connection pattern and a second circuit connection pattern;
a part, which serves as the first pole of the switching transistor, of the source/drain doped region of the active layer pattern of the switching transistor is connected to the corresponding signal reading line through a corresponding first circuit connection pattern, and an orthographic projection of the corresponding first circuit connection pattern on the plane, where the second electrode is located, intersects the first edge; and
a part, which serves as the second pole of the switching transistor, of the source/drain doped region of the active layer pattern of the switching transistor is connected to the first electrode of the photoelectric conversion structure in the same detection pixel unit through a corresponding second circuit connection pattern, and an orthographic projection of the corresponding second circuit connection pattern on the plane, where the second electrode is located, intersects the fourth edge.

In some embodiments, the signal reading circuit includes a reset transistor, a source follower transistor, and a selection transistor;
the gate of the reset transistor is connected to a reset control line, a first pole of the reset transistor is connected to a reset voltage supply line, and a second pole of the reset transistor is connected to the first electrode of the photoelectric conversion structure;
the gate of the source follower transistor is connected to the first electrode of the photoelectric conversion structure, a first pole of the source follower transistor is connected to an operating voltage supply line, and a second pole of the source follower transistor is connected to a first pole of the selection transistor;
the gate of the selection transistor is connected to the corresponding gate line, and a second pole of the selection transistor is connected to the corresponding signal reading line.

In some embodiments, the reset transistor, the source follower transistor, and the selection transistor each are the superposed transistor.

In some embodiments, the second electrode has a first edge, a second edge, a third edge, and a fourth edge, the first edge and the second edge are opposite to each other in the second direction, the third edge and the fourth edge are opposite to each other in the first direction;
the second electrode includes a first sub-region and a second sub-region arranged in the second direction, the channel region of the source follower transistor is in the first sub-region, both of the channel region of the reset transistor and the channel region of the selection transistor are in the second sub-region; and
an orthographic projection of the gate of the source follower transistor on a plane, where the second electrode is located, intersects the third edge, an orthographic projection of the gate of the reset transistor on the plane, where the second electrode is located, intersects the second edge, and an orthographic projection of the gate of the selection transistor on the plane, where the second electrode is located, intersects the fourth edge.

In some embodiments, the reset control line, the bias voltage supply line, the gate line, and the first electrode are arranged in the same layer, and the reset control line and the bias voltage supply line each extend in a second direction;
one of the bias voltage supply line corresponding to the detection pixel unit and the reset control line corresponding to the detection pixel unit is on a side closer to the third edge of the second electrode in the detection pixel unit, and the other of the bias voltage supply line and the reset control line is on a side closer to the fourth edge of the second electrode in the detection pixel unit;
the gate line corresponding to the detection pixel unit is on a side closer to the fourth edge of the second electrode in the detection pixel unit; and
a part of the first electrode of the photoelectric conversion structure, which is in contact with the gate of the source follower transistor, is on a side closer to the third edge of the second electrode in the detection pixel unit.

In some embodiments, the photo detection substrate further includes:
a wiring layer on a side of the superposed transistor away from the base substrate, where the wiring layer includes the reset voltage supply line, the operating voltage supply line, and the signal reading line, and the reset voltage supply line and the operating voltage supply line each extend in the first direction;
the operating voltage supply line corresponding to the detection pixel unit is on a side closer to the first edge of the second electrode in the detection pixel unit; and
the reset voltage supply line and the signal reading line corresponding to the detection pixel unit are on a side closer to the second edge of the second electrode in the detection pixel unit.

In some embodiments, the photo detection substrate further includes:
a circuit connection pattern layer between the superposed transistor and the wiring layer, where the circuit connection pattern layer includes a first circuit connection pattern, a second circuit connection pattern, a third circuit connection pattern, and a fourth circuit connection pattern;
a part, which serves as the second pole of the selection transistor, of the source/drain doped region of the active layer pattern of the selection transistor is connected to the corresponding signal reading line through a corresponding first circuit connection pattern, and an orthographic projection of the corresponding first circuit connection pattern on the plane, where the second electrode is located, intersects the second edge;
a part, which serves as the first pole of the reset transistor, of the source/drain doped region of the active layer pattern of the reset transistor is connected to the first electrode of the photoelectric conversion structure through a corresponding second circuit connection pattern, and an orthographic projection of the second circuit connection pattern on the plane, where the second electrode is located, intersects the third edge;
a part, which serves as the second pole of the reset transistor, of the source/drain doped region of the active layer pattern of the reset transistor is connected to the corresponding reset voltage supply line through a corresponding third circuit connection pattern, and an orthographic projection of the corresponding third circuit connection pattern on the plane, where the second electrode is located, intersects the second edge; and
a part, which serves as the first pole of the source follower transistor, of the source/drain doped region of the active layer pattern of the source follower transistor is connected to the corresponding operating voltage supply line through a corresponding fourth circuit connection pattern, and an orthographic projection of the corresponding fourth circuit connection pattern on the plane, where the second electrode is located, intersects the first edge.

In some embodiments, the source follower transistor is the superposed transistor.

In some embodiments, the gate of the reset transistor is in the same layer as the gate of the source follower transistor, and the gate of the selection transistor is in the same layer as the gate of the source follower transistor;
the active layer pattern of the reset transistor is in the same layer as the active layer pattern of the source follower transistor, and an orthographic projection of the active layer pattern of the reset transistor on the base substrate does not overlap with the orthographic projection of the photoelectric conversion structure in the same detection pixel unit on the base substrate; and
the active layer pattern of the selection transistor is in the same layer as the active layer pattern of the source follower transistor, and an orthographic projection of the active layer pattern of the selection transistor on the base substrate does not overlap with the orthographic projection of the photoelectric conversion structure in the same detection pixel unit on the base substrate.

In some embodiments, both of the reset transistor and the selection transistor are the superposed transistors; and
the source follower transistor is between the photoelectric conversion structure and the base substrate.

In some embodiments, a material of the active layer pattern of the source follower transistor includes amorphous silicon or polysilicon.

In some embodiments, an orthographic projection of the channel region of the active layer pattern of the source follower transistor on the base substrate is within the orthographic projection of the photoelectric conversion structure in the same detection pixel unit on the base substrate; and
an orthographic projection of at least a part of the source/drain doped region of the active layer pattern of the source follower transistor on the base substrate is outside the orthographic projection of the photoelectric conversion structure in the same detection pixel unit on the base substrate.

In a second aspect, an embodiment of the present disclosure further provides an image sensor, including the a photo detection substrate as provided in the first aspect.

In a third aspect, an embodiment of the present disclosure further provides an electronic apparatus, including the image sensor as provided in the second aspect.

### BRIEF DESCRIPTION OF DRAWINGS

FIG. 1 is a schematic diagram illustrating a circuit structure of a detection pixel unit in a photo detection substrate according to an embodiment of the present disclosure;

FIG. 2 is a schematic top view of the detection pixel unit shown in FIG. 1;

FIG. 3 is a schematic top view of a plurality of detection pixel units in the present disclosure;

FIG. 4 is a schematic cross-sectional view taken along a line A-A′ in FIG. 2;

FIGS. 5A to 5E are schematic cross-sectional views of intermediate structures of a photo detection substrate during manufacturing the photo detection substrate;

FIGS. 6A to 6E are schematic top views of intermediate structures of a photo detection substrate during manufacturing the photo detection substrate;

FIG. 7 is a graph schematically illustrating light transmittance of an active layer pattern of a superposed transistor, light transmittance of a gate of the superposed transistor, and quantum energy efficiency of a photoelectric conversion structure in an embodiment of the present disclosure.

FIG. 8 is a graph illustrating a comparison between negative bias temperature illumination stress of a transistor having an active layer pattern made of an oxide semiconductor material doped with a rare earth element and negative bias temperature illumination stress of a transistor having an active layer pattern made of a conventional oxide semiconductor material un-doped with a rare earth element;

FIG. 9 is a graph illustrating a comparison between threshold voltage of a transistor with a shielding electrode under the transistor and threshold voltage of a transistor without a shielding electrode under the transistor;

FIG. 10 is a schematic diagram illustrating another circuit structure of a detection pixel unit in a photo detection substrate according to an embodiment of the present disclosure;

FIG. 11 is a schematic top view of the detection pixel unit shown in FIG. 10;

FIG. 12 is a schematic cross-sectional view taken along a line B-B′ in FIG. 11;

FIG. 13 is a schematic cross-sectional view taken along a line C-C′ in FIG. 11;

FIG. 14 is a schematic cross-sectional view taken along a line D-D′ in FIG. 11;

FIG. 15 is a schematic cross-sectional view of a part of a photo detection substrate in a case where a detection pixel unit in the photo detection substrate employs the circuit structure shown in FIG. 10; and

FIG. 16 is another schematic cross-sectional view of a part of a photo detection substrate in a case where a detection pixel unit in the photo detection substrate employs the circuit structure shown in FIG. 10.

### DETAIL DESCRIPTION OF EMBODIMENTS

In order to enable one of ordinary skill in the art to better understand the technical solutions of the present disclosure, a photo detection substrate, an image sensor and an electronic apparatus provided by the present disclosure will be further described in detail below with reference to the accompanying drawings.

Numerous specific details of the present disclosure, such as structures, materials, dimensions, processing methods and techniques of the components, are set forth in the following description in order to provide a more thorough understanding of the present disclosure. However, as will be understood by one of ordinary skill in the art, the present disclosure may not be implemented according to these specific details.

The use of “first”, “second”, and the like in the present disclosure is not intended to indicate any order, quantity, or importance, but rather serves to distinguish one element from another. The word “including”, “includes”, or the like means that the element or item preceding the word includes the element or item listed after the word and its equivalent, but does not exclude other elements or items. The term “coupled”, “connected”, or the like is not restricted to physical or mechanical connections, but may include electrical connections, whether direct or indirect.

A transistor employed in the embodiment of the present disclosure may be a thin film transistor, a field effect transistors, or other devices having the same characteristics. The transistor includes a gate and an active layer pattern, where the active layer pattern includes a channel region and a source/drain doped region. The source/drain doped region refers to a region, which has certain conductivity, in a semiconductor material, formed by performing a processing, for example, doping, on the semiconductor material. The source/drain doped region in the active layer pattern may serve as a source and a drain of the transistor. There is no difference in essence between the drain and the source of each transistor in the embodiment of the present disclosure. For distinguishing the two poles of the transistor other than the control pole (i.e., the gate), one of the drain and the source is referred to as a first pole, and the other of the drain and the source is referred to as a second pole. The channel region refers to a region which is between the source and the drain in the active layer pattern and can conduct electricity when the transistor is in a turned-on state (controlled by a gate voltage). Generally, the channel region is a region, which overlaps the gate in a direction perpendicular to a base substrate, in the active layer pattern.

In addition, two structures in a same layer described in the embodiment of the present disclosure mean that the two structures are formed by patterning a same material thin film layer. That is, the two structures may be simultaneously obtained by patterning the same material thin film layer.

The term “about”, “around”, or “approximately” as used in the embodiment of the present disclosure includes the stated values and means within an acceptable range of deviation for the particular value as determined by one of ordinary skill in the art in view of the measurement in question and the error associated with the measurement of the particular quantity (i.e., the limitations of the measurement system). For example, the term “about” may mean a difference from the stated value within one or more standard deviations, or within ±30%, ±20%, ±10%, or ±5%.

In an APS structure, an operating state of the thin film transistor in a signal reading circuit directly affects reading of an electrical signal, and thus the stability of the thin film transistor is particularly important. However, in practical applications, it is found that the semiconductor material contained in the active layer pattern in the thin film transistor is very susceptible to water, oxygen and hydrogen, resulting in poor stability. The semiconductor material is particularly susceptible to hydrogen, and the hydrogen permeation may cause the semiconductor material contained in the active layer pattern to be transformed into a conductor, so that the electrical characteristics of the thin film transistor are changed.

Specifically, in the related art, all the thin film transistors in the signal reading circuit are each located between a photodiode and the base substrate. That is, the manufacturing process of all the thin film transistors in the related art is completed prior to the manufacturing process of the photodiodes. A large amount of hydrogen-related particles may be generated in the deposition process of the photodiodes. When the hydrogen-related particles penetrate into the channel region of the active layer pattern in the thin film transistor, the electrical characteristics of the channel region may be changed, for example, the threshold voltage of the thin film transistor is severely shifted, thereby affecting the overall performance of the APS.

In addition, the thin film transistor and the photodiode are staggered in the related art. In a high-resolution product, a size of a pixel is small, an effective area of the photodiode is compressed, so that the electric signal output by the photodiode is weak, which is not beneficial to subsequent detection.

To effectively solve at least one technical problem existing in the related art, an embodiment of the present disclosure provides a photo detection substrate.

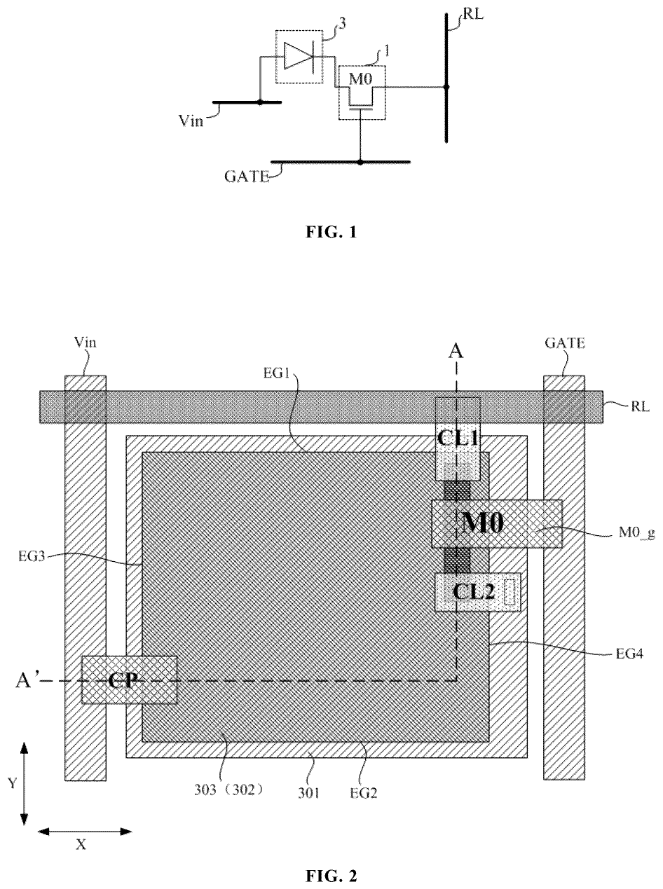

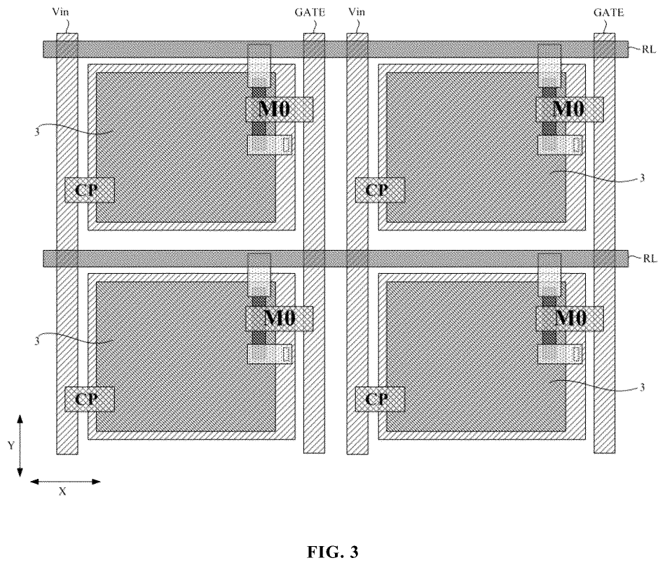

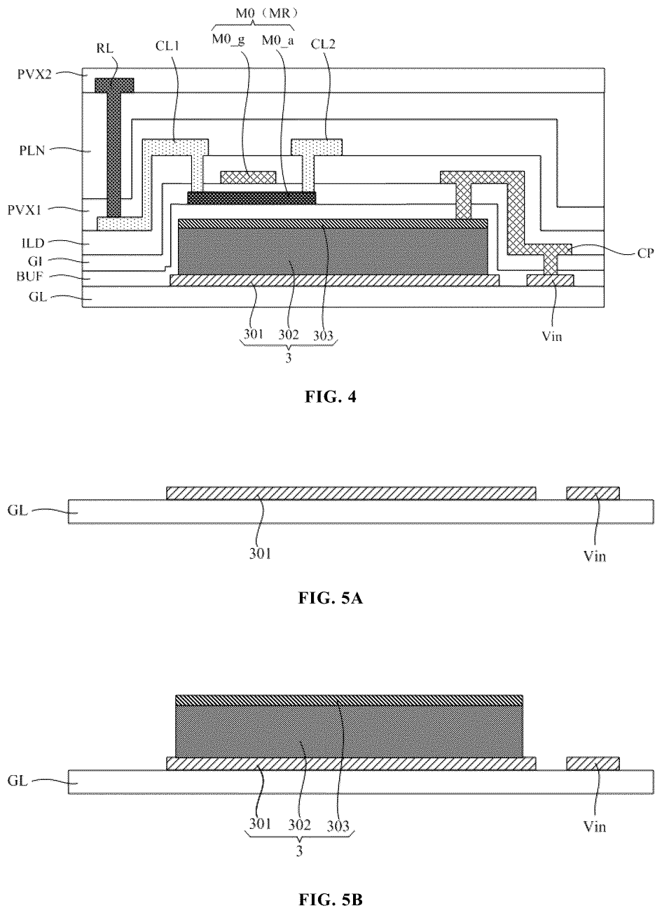

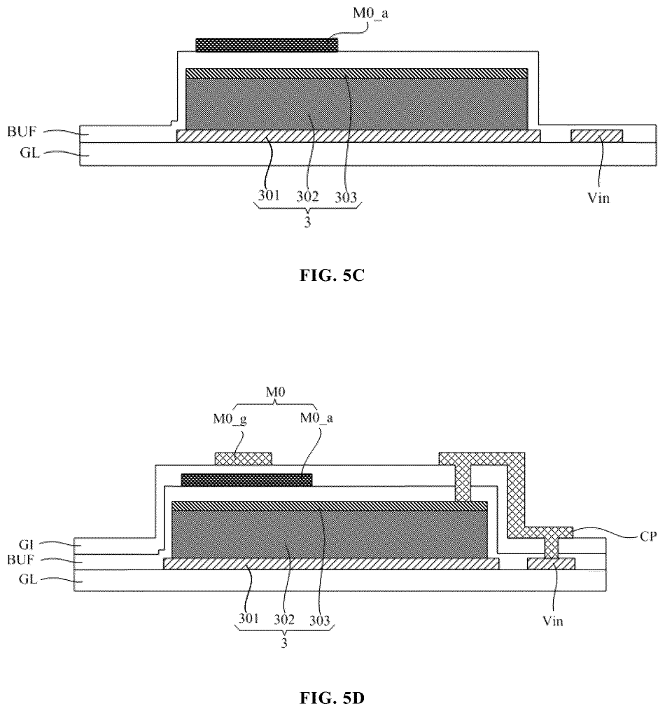

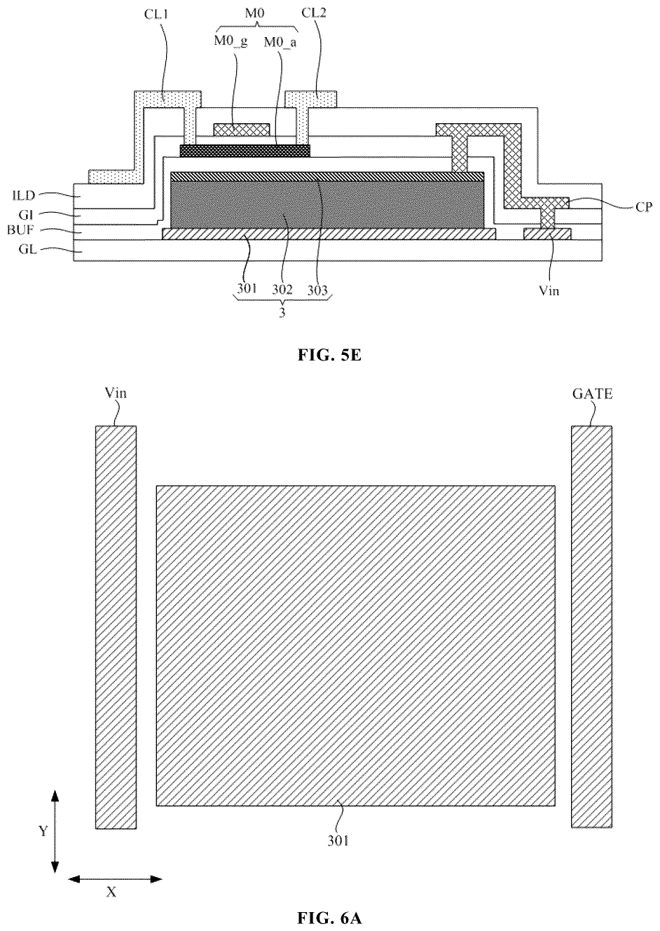

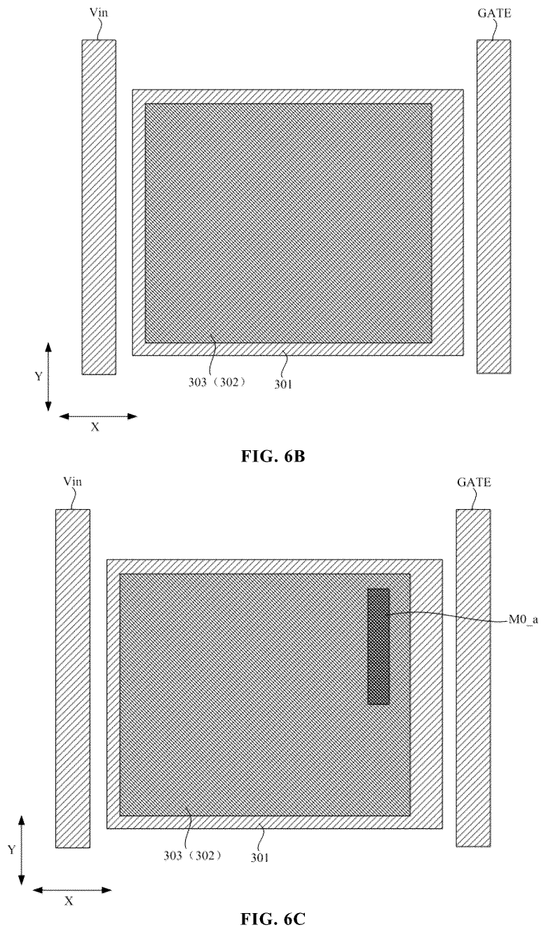

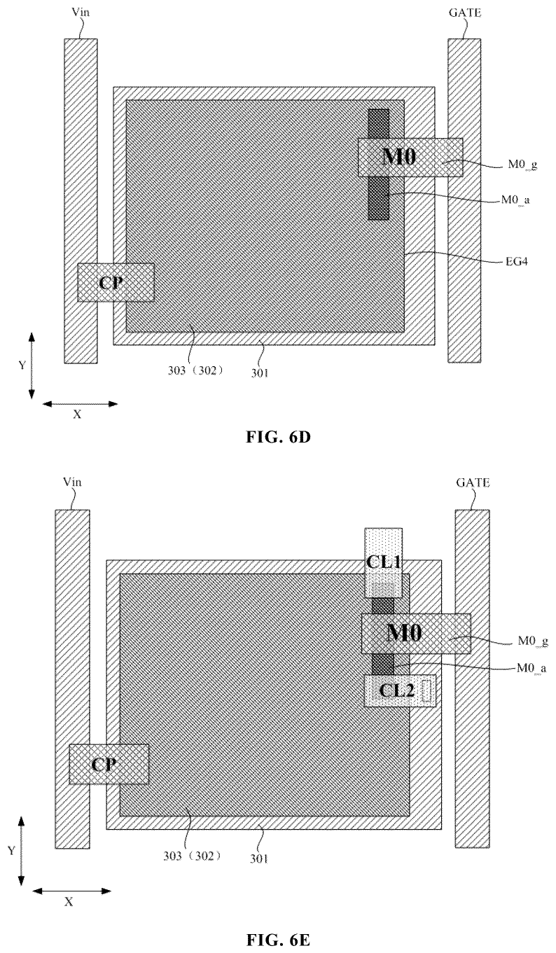

FIG. 1 is a schematic diagram illustrating a circuit structure of a detection pixel unit in a photo detection substrate according to an embodiment of the present disclosure, FIG. 2 is a schematic top view diagram of the detection pixel unit shown in FIG. 1, FIG. 3 is a schematic top view diagram of a plurality of detection pixel units according to the present disclosure, FIG. 4 is a schematic cross-sectional view taken along a line A-A′ in FIG. 2, FIG. 5A to 5E are schematic cross-sectional views of intermediate structures of a photo detection substrate during manufacturing the photo detection substrate, and FIGS. 6A to 6E are schematic top views of the intermediate structures of the photo detection substrate during manufacturing the photo detection substrate. As shown in FIGS. 1 to 6E, the photo detection substrate includes a base substrate and a plurality of detection pixel units.

The detection pixel units are located on the base substrate GL, and the detection pixel units each include a signal reading circuit 1 and a photoelectric conversion structure 3. The signal reading circuit 1 includes at least one transistor including a gate and an active layer pattern. The active layer pattern includes a channel region and a source/drain doped region. At least one transistor in the signal reading circuit 1 is a superposed transistor MR. The superposed transistor MR is located on a side of the photoelectric conversion structure 3 away from the base substrate GL. An orthographic projection of the active layer pattern of the superposed transistor MR on the base substrate GL overlaps an orthographic projection of the photoelectric conversion structure 3 in the same detection pixel unit on the base substrate GL. A material of the gate of the superposed transistor MR includes a transparent conductive material.

In the embodiment of the present disclosure, by setting at least one transistor in the signal reading circuit 1 as the superposed transistor MR on the side of the photoelectric conversion structure 3 away from the base substrate GL, that is, the manufacturing process of the superposed transistor MR is performed subsequent to the manufacturing process of the photoelectric conversion structure 3, the problem that the hydrogen-related particles in the manufacturing process of the photoelectric conversion structure 3 penetrate into the channel region of the superposed transistor MR can be prevented, so that the electrical characteristics of the channel region of the superposed transistor MR can be ensured to be stable. Furthermore, alternatively, an orthographic projection of the channel region of the active layer pattern of the superposed transistor MR on the base substrate GL overlaps the orthographic projection of the photoelectric conversion structure 3 in the same detection pixel unit on the base substrate GL.

Meanwhile, the orthographic projections of the active layer pattern of the superposed transistor MR and the photoelectric conversion structure 3 on the base substrate GL overlap each other, so that the superposed transistor MR and the photoelectric conversion structure 3 can be stacked in the direction perpendicular to the base substrate GL, which is beneficial to increase an overall size of the photoelectric conversion structure 3 in the detection pixel unit. In addition, through stacking the superposed transistor MR and the photoelectric conversion structure 3, the gate of superposed transistor MR will inevitably overlap the photoelectric conversion structure 3 in the direction of perpendicular to base substrate GL. In this case, the gate of the superposed transistor MR is made of a transparent conducting material, so that the gate of the superposed transistor MR can be prevented from shielding light of the photoelectric conversion structure 3, and an actual irradiated area of photoelectric conversion structure 3 can be effectively improved, thereby an intensity of an electrical signal output from the photodiode outputs can be improved, which is beneficial for subsequent detection.

Based on the above, it can be seen that with the technical solution of the present disclosure, on one hand, the influence of the manufacturing process of the photoelectric conversion structure 3 on the channel region of at least a portion of the transistors (which may be designed according to actual requirements, and specific examples may be referred to the following description) in the signal reading circuit 1 can be effectively prevented, and on the other hand, it is beneficial to improve the overall size and the actual irradiated area of the photoelectric conversion structure 3, and it is beneficial to improve the intensity of the electrical signal output from the photodiode, which is beneficial for the subsequent detection.

In some embodiments, the material of the gate of the superposed transistor MR includes Indium Tin Oxide (ITO).

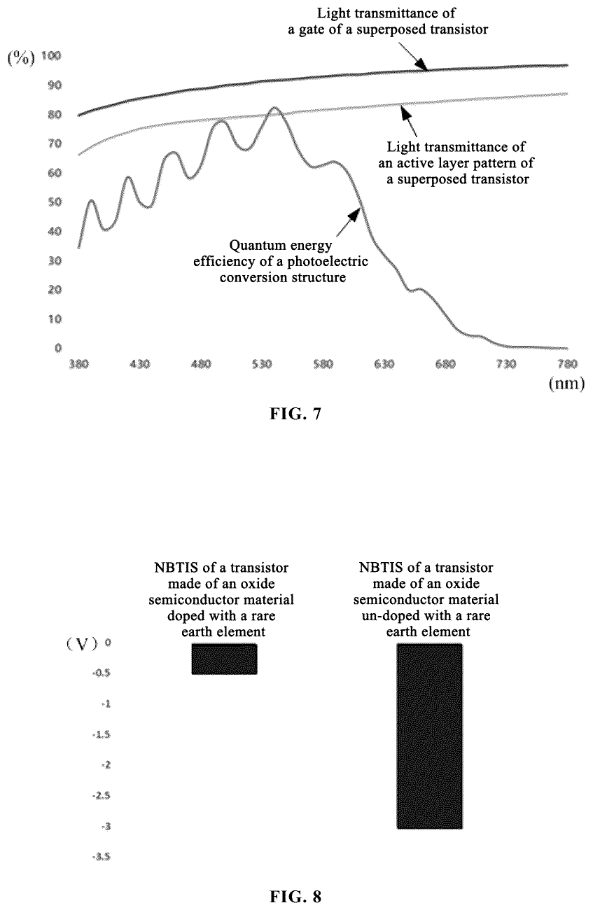

FIG. 7 is a graph schematically illustrating light transmittance of an active layer pattern of a superposed transistor MR, light transmittance of a gate of the superposed transistor, and quantum energy efficiency of a photoelectric conversion structure in an embodiment of the present disclosure. As shown in FIG. 7, a curve of light transmittance of the active layer pattern of the superposed transistor MR varying with wavelength of light, a curve of light transmittances of the gate of the superposed transistor MR varying with wavelength of light, and a curve of quantum energy efficiency of the photoelectric conversion structure 3 varying with wavelengths of light are illustrated. Based on FIG. 7, it can be seen that when the wavelength of light is in a range of 530 nm to 570 nm, the active layer pattern and the gate of the superposed transistor MR exhibit better light transmittance and the photoelectric conversion structure 3 has higher quantum energy efficiency. Therefore, in the embodiment of the present disclosure, it is preferable that the light for detection is green light, and the center wavelength is about 550 nm.

In an embodiment of the present disclosure, the gate of the superposed transistor MR is made of a transparent conductive material, that is, light passing through the gate of the superposed transistor MR may irradiate the channel region of the superposed transistor MR (and then may reach the photoelectric conversion structure 3 through the channel region). In this case, the light has a certain influence on the electrical characteristics of the channel region of the superposed transistor MR, resulting in a shift of the electrical characteristics of the channel region of the superposed transistor MR.

Therefore, the material of the active layer pattern of the superposed transistor MR is improved in the embodiment of the disclosure. Specifically, the material of the active layer pattern of the superposed transistor MR employs a metal oxide semiconductor material with high mobility and high light stability, such as any one or more of Indium Zinc Oxide (IZO), Indium Gallium Zinc Oxide (IGZO), Indium Gallium Zinc Tin Oxide (IGZTO), Indium Gallium Oxide (IGO), or Indium Zinc Tin Oxide (IZTO) based materials, each of which is doped with rare earth elements. Specifically, the metal oxide semiconductor material may be indium zinc oxide doped with lanthanum (La) element or praseodymium (Pr) element, indium zinc oxide doped with cerium (Ce) element, indium gallium zinc oxide (IGZO) doped with praseodymium element, or the like.

FIG. 8 is a graph illustrating a comparison between Negative Bias Temperature Illumination Stress (NBTIS) of a transistor having an active layer pattern made of an oxide semiconductor material doped with a rare earth element and NBTIS of a transistor having an active layer pattern made of a conventional oxide semiconductor material un-doped with a rare earth element. As shown in FIG. 8, a negative drift amount (about 0.5V) of the threshold voltage of the transistor having the active layer pattern made of the oxide semiconductor material doped with a rare earth element under irradiation, is significantly less than a negative drift amount (about 3.0V) of the threshold voltage of the transistor having the active layer pattern made of the conventional oxide semiconductor material un-doped with a rare earth element under irradiation. That is, NBTIS of the transistor having the active layer pattern made of the oxide semiconductor material doped with a rare earth element is superior to that of the transistor having the active layer pattern made of the conventional oxide semiconductor material un-doped with a rare earth element. Therefore, by doping the rare earth element in the oxide semiconductor material, light stability of the transistor can be improved.

In the embodiment of the present disclosure, by employing an oxide semiconductor material doped with a rare earth element as the material of the active layer pattern of the superposed transistor MR, the light stability of the channel region of the superposed transistor MR can be effectively improved.

In some embodiments, an orthographic projection of the active layer pattern of the superposed transistor MR on the base substrate GL is within an orthographic projection of the photoelectric conversion structure 3 in the same detection pixel unit on the base substrate GL. In this case, the active layer pattern of the superposed transistor MR is arranged directly above the photoelectric conversion structure 3, which is beneficial to increase the overall size of the photoelectric conversion structure 3.

In some embodiments, the photoelectric conversion structure 3 includes a PIN photodiode and a PN photodiode, and an operating state of the photo sensor can be controlled by controlling voltages applied to the first electrode 301 and the second electrode 303. The photoelectric conversion layer 302 may include a P-type semiconductor layer (e.g., P-type Si layer) and an N-type semiconductor layer (e.g., N-type Si layer) stacked together, and in this case, the photoelectric conversion structure 3 is a PN photodiode. The photoelectric conversion layer 302 may alternatively include a P-type semiconductor layer, an intrinsic semiconductor layer (e.g., an intrinsic Si layer), and an N-type semiconductor layer, which are stacked together, and in this case, the photoelectric conversion structure 3 is a PIN photodiode. Illustratively, the intrinsic semiconductor layer is an a-Si material, the P-type semiconductor layer is an a-Si material doped with B ions, and the N-type semiconductor layer is an a-Si material doped with P ions.

In some embodiments, the second electrode 303 is a transparent electrode, and may be made of a transparent metal oxide material such as indium tin oxide, indium zinc oxide, or gallium zinc oxide. The first electrode 301 is a metal electrode, and may be made of a metal material such as copper, aluminum, titanium, or molybdenum, or an alloy material. It should be noted that in the embodiment of the present disclosure, a “transparent” structure means that the structure can transmit light, and does not mean that the structure has a light transmittance of 100%.

In some embodiments, an area of an orthographic projection of the first electrode 301 on the base substrate GL is greater than an area of an orthographic projection of the photoelectric conversion layer 302 on the base substrate GL, and the area of the orthographic projection of the photoelectric conversion layer 302 on the base substrate GL is equal to or greater than an area of an orthographic projection of the second electrode 303 on the base substrate GL.

In some embodiments, the orthographic projection of the active layer pattern of the superposed transistor MR on the base substrate GL is within the orthographic projection of the second electrode 303 of the photoelectric conversion structure 3 in the same detection pixel unit on the base substrate GL.

In practical applications, a direct current bias voltage is applied to the second electrode 303, and in this case, the second electrode 303 may serve as a shielding electrode to shield and protect the active layer pattern (including the channel region) of the superposed transistor MR, for example, to suppress an influence of charges induced in the base substrate on the electrical characteristics of the channel region of the superposed transistor MR. It is beneficial to improve the uniformity of the threshold voltage of the superposed transistors MR in different detection pixel units.

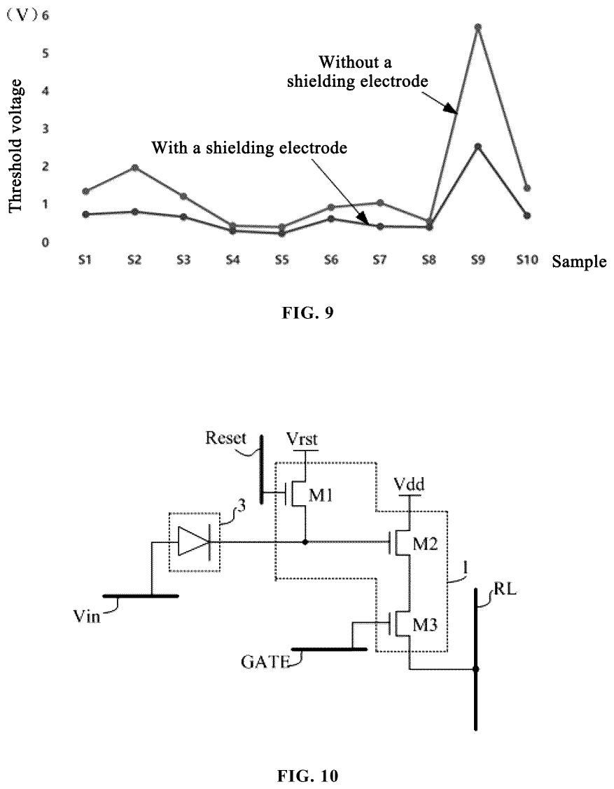

FIG. 9 is a graph illustrating a comparison between threshold voltage of a transistor with a shielding electrode under the transistor and threshold voltage of a transistor without a shielding electrode under the transistor. As shown in FIG. 9, a difference between the threshold voltages of ten different samples S1 to S10 with the shielding electrode under the transistor is significantly less than a difference between the threshold voltages of ten different samples S1 to S10 without the shielding electrode.

In some embodiments, the photo detection substrate further includes a plurality of gate lines GATE sequentially arranged along a first direction X and a plurality of signal reading lines RL sequentially arranged along a second direction Y, where the gate lines GATE each extend along the second direction Y, the signal reading lines RL each extend along the first direction X, and the first direction X and the second direction Y intersect each other. The plurality of gate lines GATE and the plurality of signal reading lines RL define a plurality of detection pixel units. The signal reading circuit 1 in the detection pixel unit is connected to a corresponding gate line GATE and a corresponding signal reading line RL. The photo detection substrate further includes a plurality of bias voltage supply lines Vin. The photoelectric conversion structure 3 includes a first electrode 301, a photoelectric conversion layer 302, and a second electrode 303, which are arranged sequentially in a direction away from the base substrate GL, where the first electrode 301 is connected to the corresponding signal reading circuit 1, and the second electrode 303 is connected to a corresponding bias voltage supply line Vin.

In some embodiments, the photo detection substrate further includes a circuit connection pattern layer, which is located on a side of the superposed transistor MR away from the base substrate GL. The circuit connection pattern layer includes a plurality of circuit connection patterns, each of which is connected to the source/drain doped region of a corresponding transistor.

In some embodiments, the signal reading line RL is located on a side of the circuit connection pattern layer away from the base substrate GL. The circuit connection pattern layer includes a first circuit connection pattern CL1. The signal reading line RL is connected to the source/drain doped region of the corresponding transistor in the signal reading circuit 1, through a corresponding first circuit connection pattern CL1.

In some embodiments, a material of the circuit connection pattern layer includes a transparent conductive material. In an embodiment of the present disclosure, the circuit connection pattern in the circuit connection pattern layer is required to be connected to the source/drain doped region of the corresponding transistor. That is, the circuit connection pattern may overlap a region where the photoelectric conversion structure 3 (especially the second electrode 303) is located. In order to prevent the circuit connection pattern from shielding light to the photoelectric conversion structure 3, it is preferable to employ a transparent conductive material, such as indium tin oxide, as the material of the circuit connection pattern layer.

In some embodiments, the first electrode 301, the bias voltage supply line Vin, and the gate line GATE are arranged in a same layer. That is, the first electrode 301, the bias voltage supply line Vin, and the gate line GATE may be simultaneously formed based on one patterning process, which is beneficial to shorten the production period.

In some embodiments, the photo detection substrate further includes a bias transmission pattern CP, through which the second electrode 303 of the photoelectric conversion structure 3 is connected to a corresponding bias voltage supply line Vin. The bias transmission pattern CP is arranged in the same layer as the gate of the superposed transistor MR. That is, the bias transmission pattern CP and the gate of the superposed transistor MR may be simultaneously formed based on one patterning process, which is beneficial to shorten the production period.

The photo detection substrate in the present disclosure will be described in detail with reference to specific examples.

With continued reference to FIGS. 1 to 6E, in some embodiments, the signal reading circuit 1 includes a switching transistor M0. A gate M0_g of the switching transistor M0 is connected to the corresponding gate line GATE, a first pole of the switching transistor M0 is connected to the first electrode 301 of the photoelectric conversion structure 3, and a second pole of the switching transistor M0 is connected to the corresponding signal reading line RL. The switching transistor M0 is the superposed transistor MR.

In the drawings, M0_g denotes the gate of the switching transistor M0, and M0_a denotes the active layer pattern (including the channel region and the source/drain doped region) of the switching transistor M0.

In some embodiments, the bias voltage supply line Vin is arranged in the same layer as the gate line GATE, and the signal reading line RL extends in the second direction Y. A bias voltage supply line Vin and a gate line GATE corresponding to the detection pixel unit are located on two opposite sides of the photoelectric conversion structure 3 in the detection pixel unit in the first direction X, respectively.

In some embodiments, the second electrode 303 has a third edge EG3 and a fourth edge EG4, which are opposite to each other in the first direction X. A gate line GATE corresponding to the detection pixel unit is located on a side closer to the fourth edge EG4 of the second electrode 303 in the detection pixel unit. An orthographic projection of the gate M0_g of the switching transistor M0 on a plane, where the second electrode 303 is located, intersects the fourth edge EG4. A bias voltage supply line Vin corresponding to the detection pixel unit is located on a side closer to the third edge EG3 of the second electrode 303 in the detection pixel unit. The photo detection substrate further includes the bias transmission pattern CP, through which the second electrode 303 of the photoelectric conversion structure 3 is connected to the corresponding bias voltage supply line Vin. The bias transmission pattern CP is arranged in the same layer as the gate of the superposed transistor MR, and an orthographic projection of the bias transmission pattern CP on the plane, where the second electrode 303 is located, intersects the third edge EG3.

In some embodiments, the second electrode 303 further has a first edge EG1 and a second edge EG2, which are opposite to each other in the second direction Y.

The photo detection substrate further includes a wiring layer, which is located on a side of the superposed transistor MR away from the base substrate GL. The wiring layer includes the signal reading line RL. A signal reading line RL corresponding to the detection pixel unit is located on a side closer to the first edge EG1 of the second electrode 303 in the detection pixel unit.

The photo detection substrate further includes a circuit connection pattern layer, which is located between the superposed transistor MR and the wiring layer. The circuit connection pattern layer includes a first circuit connection pattern CL1 and a second circuit connection pattern CL2.

A part, which serves as the first pole of the switching transistor M0, of the source/drain doped region of the active layer pattern M0_a of the switching transistor M0 is connected to the corresponding signal reading line RL through a corresponding first circuit connection pattern CL1. An orthographic projection of the first circuit connection pattern CL1 on the plane, where the second electrode 303 is located, intersects the first edge EG1.

A part, which serves as the second pole of the switching transistor M0, of the source/drain doped region of the active layer pattern M0_a of the switching transistor M0 is connected to the first electrode 301 of the photoelectric conversion structure 3 in the same detection pixel unit through a corresponding second circuit connection pattern CL2. An orthographic projection of the second circuit connection pattern CL2 on the plane, where the second electrode 303 is located, intersects the fourth edge EG4.

Referring to FIGS. 5A to 6E, a process of manufacturing the photo detection substrate may include the following steps.

First, as shown in FIGS. 5A and 6A, a first conductive layer is formed on a side of the base substrate GL, where the first conductive layer includes the first electrode 301 of the photoelectric conversion structure 3 and structures in the same layer as the first electrode 301, such as the gate line GATE and the bias voltage supply line Vin. Optionally, a material of the first conductive layer is a metal material.

Then, referring to FIGS. 5B and 6B, the photoelectric conversion layer 302 and the second electrode 303 are sequentially formed, thereby obtaining the photoelectric conversion structure 3. Then, a buffer layer BUF is formed on a side of the photoelectric conversion structure 3 away from the base substrate GL.

Next, as shown in FIGS. 5C and 6C, an active function layer including the active layer patterns of the transistors is formed on a side of the buffer layer BUF away from the base substrate GL. Optionally, a material of the active layer pattern includes an oxide semiconductor material doped with a rare earth element.

Next, a gate insulating layer GI is formed on a side of the active layer pattern away from the base substrate GL.

Next, as shown in FIGS. 5D and 6D, a second conductive layer is formed on a side of the gate insulating layer GI away from the base substrate GL, where the second conductive layer includes the gate of the superposed transistor MR and a structure in the same layer as the gate of the superposed transistor MR, such as the bias transmission pattern CP. Optionally, a material of the second conductive layer is a transparent conductive material.

Then, an interlayer dielectric layer ILD is formed.

Next, as shown in FIGS. 5E and 6E, the circuit connection pattern layer is formed on a side of the interlayer dielectric layer ILD away from the base substrate GL, where the circuit connection pattern layer includes a plurality of circuit connection patterns, each of which is connected to the source/drain doped region of a corresponding transistor. Optionally, a material of the circuit connection pattern layer includes a transparent conductive material.

Taking the manufacturing of the detection pixel unit shown in FIG. 2 as an example, the circuit connection pattern layer includes a first circuit connection pattern CL1 and a second circuit connection pattern CL2. A part, which serves as the first pole of the switching transistor M0, of the source/drain doped region of the active layer pattern M0_a of the switching transistor M0 is connected to a signal reading line RL to be formed later, through a corresponding first circuit connection pattern CL1. A part, which serves as the second pole of the switching transistor M0, of the source/drain doped region of the active layer pattern M0_a of the switching transistor M0 is connected to the first electrode 301 of the photoelectric conversion structure 3 in the same detection pixel unit through a corresponding second circuit connection pattern CL2.

Next, a first passivation layer PVX1 and a planarization layer PLN are sequentially formed.

Next, referring to FIGS. 2 and 4, the wiring layer is formed, where the wiring layer includes the signal reading lines RL, each of which is connected to the source/drain doped region of a corresponding transistor through a corresponding first circuit connection pattern CL1. Optionally, a material of the wiring layer includes a metal material.

Alternatively, a second passivation layer PVX2 is further arranged on a side of the wiring layer away from the base substrate GL.

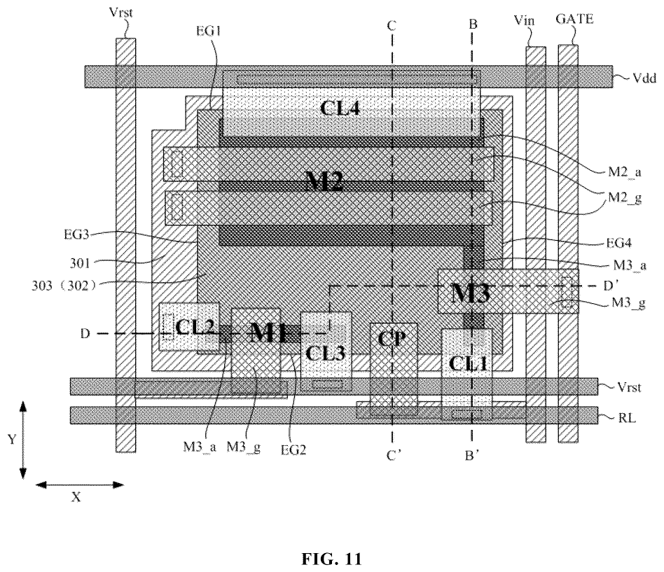

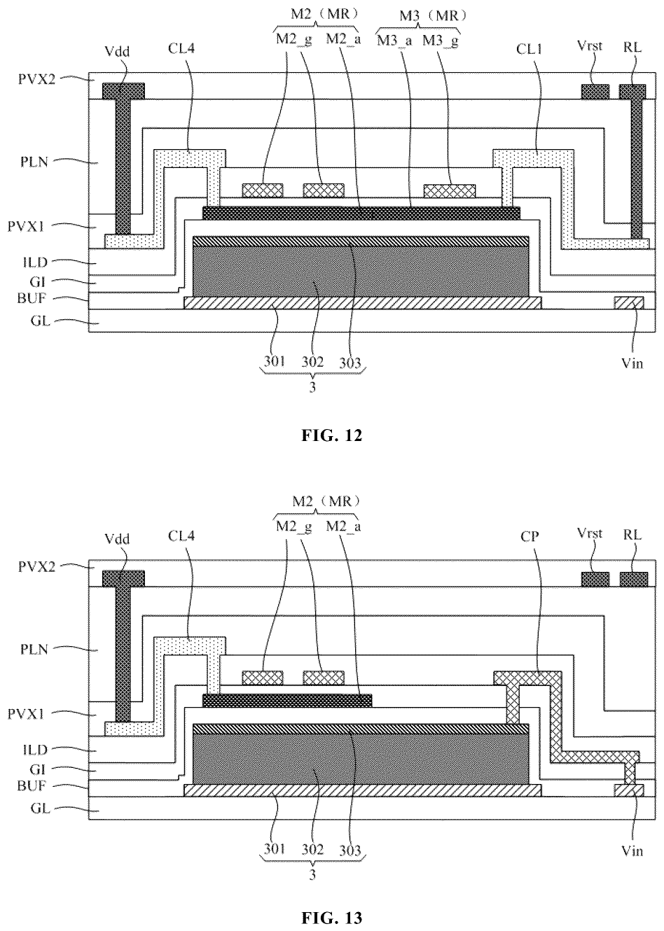

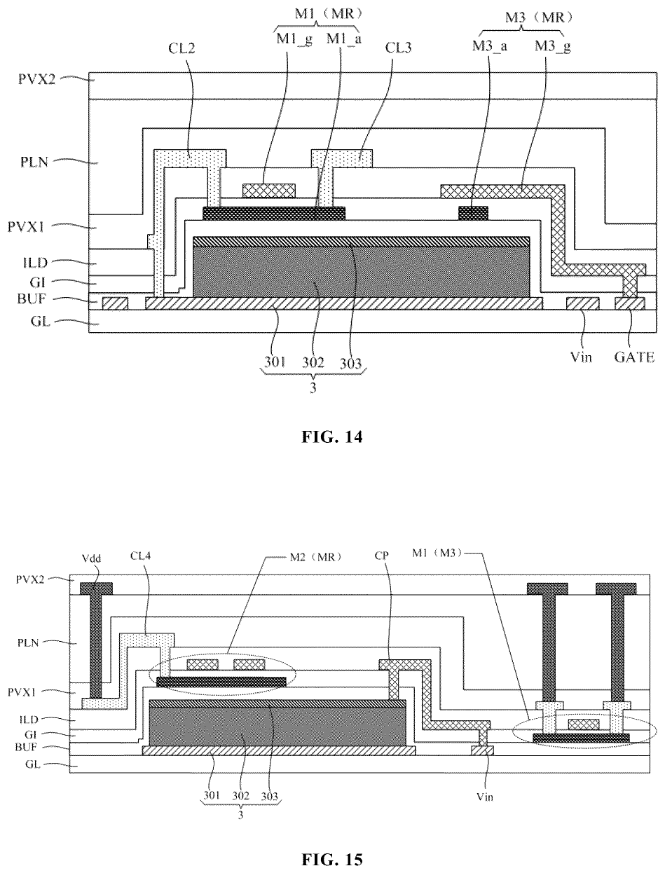

FIG. 10 is a schematic diagram illustrating another circuit structure of a detection pixel unit in a photo detection substrate according to an embodiment of the present disclosure, FIG. 11 is a schematic top view of the detection pixel unit shown in FIG. 10, FIG. 12 is a schematic cross-sectional view taken along a direction B-B′ in FIG. 11, FIG. 13 is a schematic cross-sectional view taken along a direction C-C′ in FIG. 11, and FIG. 14 is a schematic cross-sectional view taken along a direction D-D′ in FIG. 11. As shown in FIGS. 10 to 14, the signal reading circuit 1 includes a reset transistor M1, a source follower transistor M2, and a selection transistor M3.

A gate M1_g of the reset transistor M1 is connected to a reset control line RESET, a first pole of the reset transistor M1 is connected to a reset voltage supply line Vrst, and a second pole of the reset transistor M1 is connected to a first electrode 301 of a photoelectric conversion structure 3. A gate M2_g of the source follower transistor M2 is connected to a first electrode 301 of the photoelectric conversion structure 3, a first pole of the source follower transistor M2 is connected to an operating voltage supply line Vdd, and a second pole of the source follower transistor M2 is connected to a first pole of the selection transistor M3. A gate M3_g of the selection transistor M3 is connected to a corresponding gate line GATE, and a second pole of the selection transistor M3 is connected to a corresponding signal reading line RL.

In the drawings, M1_g denotes the gate of the reset transistor M1, M1_a denotes an active layer pattern (including a channel region and a source/drain doped region) of the reset transistor M1; M2_g denotes the gate of the source follower transistor M2, and M2_a denotes an active layer pattern (including a channel region and a source/drain doped region) of the source follower transistor M2; M3_g denotes the gate of the selection transistor M3, and M2_a denotes an active layer pattern (including a channel region and a source/drain doped region) of the selection transistor M3.

Referring to FIGS. 11 to 14, in some embodiments, the reset transistor M1, the source follower transistor M2, and the selection transistor M3 are all superposed transistors MR.

In some embodiments, the second electrode 303 has a first edge EG1, a second edge EG2, a third edge EG3, and a fourth edge EG4, where the first edge EG1 and the second edge EG2 are opposite to each other in the second direction Y, and the third edge EG3 and the fourth edge EG4 are opposite to each other in the first direction X.

The second electrode 303 includes a first sub-region and a second sub-region arranged in the second direction Y, where the channel region of the source follower transistor M2 is located in the first sub-region, and both of the channel region of the reset transistor M1 and the channel region of the selection transistor M3 are located in the second sub-region.

An orthographic projection of the gate M2_g of the source follower transistor M2 on a plane, where the second electrode 303 is located, intersects the third edge EG3. An orthographic projection of the gate M2_1 of the reset transistor M1 on the plane, where the second electrode 303 is located, intersects the second edge EG2. An orthographic projection of the gate M3_g of the selection transistor M3 on the plane, where the second electrode 303 is located, intersects the fourth edge EG4.

In some embodiments, the reset control line RESET, the bias voltage supply line Vin, the gate line GATE, the first electrode 301 are arranged in a same layer, and both the reset control line RESET and the bias voltage supply line Vin extend in the second direction Y.

One of a bias voltage supply line Vin and a reset control line RESET corresponding to the detection pixel unit is located on a side closer to the third edge EG3 of the second electrode 303 in the detection pixel unit, and the other of the bias voltage supply line Vin and the reset control line RESET corresponding to the detection pixel unit is located on a side closer to the fourth edge EG4 of the second electrode 303 in the detection pixel unit.

A gate line GATE corresponding to the detection pixel unit is located on a side closer to the fourth edge EG4 of the second electrode 303 in the detection pixel unit.

A part of the first electrode 301 of the photoelectric conversion structure 3, which is in contact with the gate M2_g of the corresponding source follower transistor M2, is located on a side closer to the third edge EG3 of the second electrode 303 in the detection pixel unit.

In some embodiments, the photo detection substrate further includes a wiring layer, which is located on a side of the superposed transistor MR away from base substrate GL. The wiring layer includes the reset voltage supply line Vrst, the operating voltage supply line Vdd, and the signal reading line RL. The reset voltage supply line Vrst and the operating voltage supply line Vdd each extend in the first direction X.

An operating voltage supply line Vdd corresponding to the detection pixel unit is located on a side closer to the first edge EG1 of the second electrode 303 in the detection pixel unit.

A reset voltage supply line Vrst and a signal reading line RL corresponding to the detection pixel unit each are located on a side closer to the second edge EG2 of the second electrode 303 in the detection pixel unit.

In some embodiments, the photo detection substrate further includes a circuit connection pattern layer, which is located between the superposed transistor MR and the wiring layer. The circuit connection pattern layer includes a first circuit connection pattern CL1, a second circuit connection pattern CL2, a third circuit connection pattern CL3, and a fourth circuit connection pattern CL4.

A part, which serves as the second pole of the selection transistor M3, of the source/drain doped region of the active layer pattern M3_a of the selection transistor M3 is connected to a corresponding signal reading line RL through a corresponding first circuit connection pattern CL1. An orthographic projection of the first circuit connection pattern CL1 on the plane, where the second electrode 303 is located, intersects the second edge EG2.

A part, which serves as the first pole of the reset transistor M1, of the source/drain doped region of the active layer pattern M1_a of the reset transistor M1 is connected to the first electrode 301 of the corresponding photoelectric conversion structure 3 through a corresponding second circuit connection pattern. An orthographic projection of the second circuit connection pattern CL2 on the plane, where the second electrode 303 is located, intersects the third edge EG3.

A part, which serves as the second pole of the reset transistor M1, of the source/drain doped region of the active layer pattern M1_a of the reset transistor M1 is connected to a corresponding reset voltage supply line Vrst through a corresponding third circuit connection pattern. An orthographic projection of the third circuit connection pattern CL3 on the plane, where the second electrode 303 is located, intersects the second edge EG2.

A part, which serves as the first pole of the source follower transistor M2, of the source/drain doped region of the active layer pattern M2_a of the source follower transistor M2 is connected to a corresponding operating voltage supply line Vdd through a corresponding fourth circuit connection pattern. An orthographic projection of the fourth circuit connection pattern CL4 on the plane, where the second electrode 303 is located, intersects the first edge EG1.

The source follower transistor M2 is only exemplarily shown in FIG. 11 to include two gates M2_g, which is beneficial to improve the current saturation of the source follower transistor M2, and this case is only an alternative implementation in the embodiments of the present disclosure, and does not limit the technical solution of the present disclosure.

It should be noted that, in a case where the reset transistor M1, the source follower transistor M2, and the selection transistor M3 are all superposed transistors MR, the arrangement of the reset transistor M1, the source follower transistor M2, and the selection transistor M3 above the photoelectric conversion structure 3 shown in FIG. 11 is only an alternative implementation in the embodiments of the present disclosure, and does not limit the technical solution of the present disclosure.

It should be noted that a process of manufacturing the photo detection substrate including the detection pixel unit shown in FIG. 11 is similar to the process of manufacturing the photo detection substrate including the detection pixel unit shown in FIG. 2, and related descriptions may be referred to corresponding contents in the foregoing embodiments, and are not repeated herein.

FIG. 15 is a schematic cross-sectional view of a part of a photo detection substrate in a case where a detection pixel unit in the photo detection substrate employs the circuit structure shown in FIG. 10. As shown in FIG. 15, the source follower transistor M2 is selectively designed as the superposed transistor MR, while the reset transistor M1 and the selection transistor M3 are not the superposed transistor MR, which is different from the previous embodiment where the reset transistor M1, the source follower transistor M2 and the selection transistor M3 are all the superposed transistors MR.

As an alternative embodiment, the gate M1_g of the reset transistor M1 is arranged in the same layer as the gate M2_g of the source follower transistor M2, and the gate M3_g of the selection transistor M3 is arranged in the same layer as the gate M2_g of the source follower transistor M2. The active layer pattern M1_a of the reset transistor M1 is arranged in the same layer as the active layer pattern M2_a of the source follower transistor M2, and there is no overlap between an orthographic projection of the active layer pattern M1_a of the reset transistor M1 on the base substrate GL and an orthographic projection of the photoelectric conversion structure 3 in the same detection pixel unit on the base substrate GL. The active layer pattern M3_a of the selection transistor M3 is arranged in the same layer as the active layer pattern M2_a of the source follower transistor M2, and there is no overlap between an orthographic projection of the active layer pattern M3_a of the selection transistor M3 on the base substrate GL and the orthographic projection of the photoelectric conversion structure 3 in the same detection pixel unit on the base substrate GL.

That is, although the reset transistor and the selection transistor M3 are located on the side of the photoelectric conversion structure 3 away from the base substrate GL, the active layer patterns M3_a of the reset transistor and the selection transistor M3 do not overlap the photoelectric conversion structure 3 in a direction perpendicular to the base substrate GL.

Generally, the source follower transistor M2 has the largest size, and the source follower transistor M2 has the highest requirement for the stability of the electrical characteristics, so that only the source follower transistor M2 may be selectively arranged right above the photoelectric conversion structure 3 as a reset transistor, and the other reset transistors each are arranged on either side of the photoelectric conversion structure 3. With such a design, the requirement of the source follower transistor M2 on the stability of the electrical characteristics can be met, and meanwhile, it is convenient to design the wiring of the detection pixel unit.

It should be noted that a process of manufacturing the photo detection substrate including the detection pixel unit shown in FIG. 15 is similar to the process of manufacturing the photo detection substrate including the detection pixel unit shown in FIG. 2, and related descriptions may be referred to corresponding contents in the foregoing embodiments, and are not repeated herein.

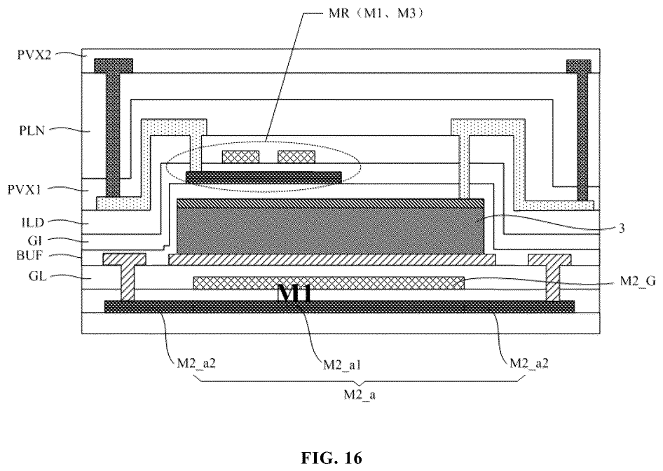

FIG. 16 is another schematic cross-sectional view of a part of a photo detection substrate in a case where a detection pixel unit in the photo detection substrate employs the circuit structure shown in FIG. 10. As shown in FIG. 16, the reset transistor M1 and the selection transistor M3 each are selectively designed as the superposed transistor MR, and the source follower transistor M2 is located between the photoelectric conversion structure 3 and the base substrate GL, which is different from the scheme shown in FIG. 15 where the source follower transistor M2 is selectively designed as the superposed transistor MR.

Alternatively, a material of the active layer pattern M2_a of the source follower transistor M2 includes amorphous silicon or polysilicon. Low temperature polysilicon is described as an example herein. In this case, the photo detection substrate is a photo detection substrate based on the LTPO technology. The source follower transistor M2 is a low temperature polysilicon transistor, so that transconductance thereof can be improved, and signal amplification ratio thereof can be improved. The reset transistor M1 and the selection transistor M3 are metal oxide transistors, so that off-state leakage current thereof can be effectively reduced.

In some embodiments, an orthographic projection of the channel region M2_a1 of the active layer pattern M2_a of the source follower transistor M2 on the base substrate GL is within an orthographic projection of the photoelectric conversion structure 3 in the same detection pixel unit on the base substrate GL; and an orthographic projection of at least a part of the source/drain doped region M2_a2 of the active layer pattern M2_a of the source follower transistor M2 on the base substrate GL is outside the orthographic projection of the photoelectric conversion structure 3 in the same detection pixel unit on the base substrate GL.

In the present disclosure, the source follower transistor M2 of low temperature polysilicon is placed below the photoelectric conversion structure 3, and the photoelectric conversion structure 3 the source follower transistor M2 are stacked together, which is beneficial to increase the overall size of the photoelectric conversion structure 3.

It should be noted that the process of manufacturing the photo detection substrate including the detection pixel unit shown in FIG. 16 includes not only the steps of manufacturing the photo detection substrate including the detection pixel unit shown in FIG. 2, but also steps of forming the source follower transistor M2 (for example, the source follower transistor may be formed through a process of manufacturing the low temperature polysilicon transistor) prior to the step of forming the first conductive layer, and the specific process is not repeated herein.

It should be noted that, the present disclosure is not limited to the relative positions of the reset transistor M1, the source follower transistor M2, and the selection transistor M3 in the direction parallel to the base substrate GL in the detection pixel unit shown in FIGS. 15 and 16.

Based on the same inventive concept, an embodiments of the present disclosure further provide an image sensor, which includes the photo detection substrate provided in the above embodiments, and specific description of the photo detection substrate may be referred to the foregoing description, and is not repeated here.

The image sensor may include peripheral circuits such as a row driver circuit, a column driver circuit, an amplifier circuit, and a pre-processing circuit, in addition to the photo detection substrate. These circuits are all conventional structures in the art, and the detailed circuit structure and operation process thereof are not described herein again.

Based on the same inventive concept, an embodiment of the present disclosure further provides an electronic apparatus including an image sensor, where the image sensor employs the above-described image sensor. The electronic apparatus may be a digital camera, a mobile phone, a tablet computer, a notebook computer, or the like.

It will be understood that the above embodiments are merely exemplary embodiments adopted to illustrate the principles of the present disclosure, and the present disclosure is not limited thereto. It will be apparent to one of ordinary skill in the art that various modifications and improvements can be made without away from the spirit and essence of the present disclosure, and such modifications and improvements are also considered to be within the scope of the present disclosure.

1. A photo detection substrate, comprising:
a base substrate; and
a plurality of detection pixel units on the base substrate, wherein each of the plurality of detection pixel units comprises a signal reading circuit and a photoelectric conversion structure,
wherein the signal reading circuit comprises at least one transistor, each of the at least one transistor comprises a gate and an active layer pattern, and the active layer pattern comprises a channel region and a source/drain doped region; and
at least one of the at least one transistor in the signal reading circuit is a superposed transistor on a side of the photoelectric conversion structure away from the base substrate, an orthographic projection of the active layer pattern of the superposed transistor on the base substrate overlaps an orthographic projection of the photoelectric conversion structure in the same detection pixel unit on the base substrate, and a material of the gate of the superposed transistor comprises a transparent conductive material.

2. The photo detection substrate according to claim 1, wherein a material of the active layer pattern of the superposed transistor comprises an oxide semiconductor material doped with a rare earth element.

3. The photo detection substrate according to claim 1, wherein the orthographic projection of the active layer pattern of the superposed transistor on the base substrate is within the orthographic projection of the photoelectric conversion structure in the same detection pixel unit on the base substrate.

4. The photo detection substrate according to claim 1, further comprising a plurality of gate lines sequentially arranged along a first direction and a plurality of signal reading lines sequentially arranged along a second direction, wherein the plurality of gate lines each extend along the second direction, the plurality of signal reading lines each extend along the first direction, and the first direction and the second direction intersect each other;
the plurality of gate lines and the plurality of signal reading lines define the plurality of detection pixel units, and the signal reading circuit in each of the plurality of detection pixel units is connected to a corresponding one of the plurality of gate lines and a corresponding one of the plurality of signal reading lines;
the photo detection substrate further comprises a plurality of bias voltage supply lines; and
the photoelectric conversion structure comprises a first electrode, a photoelectric conversion layer and a second electrode, the first electrode is connected to a corresponding one of the signal reading circuits, and the second electrode is connected to a corresponding one of the plurality of bias voltage supply lines.

5. The photo detection substrate according to claim 4, further comprising:
a circuit connection pattern layer on a side of the superposed transistor away from the base substrate, wherein the circuit connection pattern layer comprises a plurality of circuit connection patterns, and each of the plurality of circuit connection patterns is connected to the source/drain doped region of a corresponding transistor,
wherein a material of the circuit connection pattern layer comprises a transparent conductive material.

6. The photo detection substrate according to claim 5, wherein the signal reading line is on a side of the circuit connection pattern layer away from the base substrate; and
the circuit connection pattern layer comprises a first circuit connection pattern; and the signal reading line is connected to the source/drain doped region of a transistor in the signal reading circuit through the first circuit connection pattern corresponding to the transistor.

7. (canceled)

8. The photo detection substrate according to claim 4, wherein the first electrode, the bias voltage supply line, and the gate line are in the same layer,
the photo detection substrate further comprises a bias transmission pattern, wherein the second electrode of the photoelectric conversion structure is connected to the corresponding bias voltage supply line through the bias transmission pattern; and
the bias transmission pattern is arranged in the same layer as the gate of the superposed transistor.

9. (canceled)

10. The photo detection substrate according to claim 4, wherein the signal reading circuit comprises a switching transistor;
the gate of the switching transistor is connected to the corresponding gate line, a first pole of the switching transistor is connected to the first electrode of the photoelectric conversion structure, and a second pole of the switching transistor is connected to the corresponding signal reading line; and
the switching transistor is the superposed transistor.

11. The photo detection substrate according to claim 10, wherein the bias voltage supply line is in the same layer as the gate line, and the signal reading line extends in the second direction; and
one of the bias voltage supply lines and one of the gate lines corresponding to the detection pixel unit are on two opposite sides of the photoelectric conversion structure in the detection pixel unit in the first direction, respectively.

12. The photo detection substrate according to claim 11, wherein the second electrode has a third edge and a fourth edge opposite to each other in the first direction;
the gate line corresponding to the detection pixel unit is on a side closer to the fourth edge of the second electrode in the detection pixel unit, and an orthographic projection of the gate of the switching transistor on a plane, where the second electrode is located, intersects the fourth edge;
the bias voltage supply line corresponding to the detection pixel unit is on a side closer to the third edge of the second electrode in the detection pixel unit; and
the photo detection substrate further comprises a bias voltage transmission pattern, the second electrode of the photoelectric conversion structure is connected to the corresponding bias voltage supply line through the bias voltage transmission pattern, the bias voltage transmission pattern is in the same layer as the gate of the superposed transistor, and an orthographic projection of the bias voltage transmission pattern on the plane, where the second electrode is located, intersects the third edge.

13. The photo detection substrate according to claim 12, wherein the second electrode further has a first edge and a second edge opposite to each other in the second direction;
the photo detection substrate further comprises a wiring layer on a side of the superposed transistor away from the base substrate, and the wiring layer comprises the signal reading line;
one of the signal reading lines corresponding to the detection pixel unit is on a side closer to the first edge of the second electrode in the detection pixel unit;
the photo detection substrate further comprises a circuit connection pattern layer between the superposed transistor and the wiring layer, the circuit connection pattern layer comprises a first circuit connection pattern and a second circuit connection pattern;
a part, which serves as the first pole of the switching transistor, of the source/drain doped region of the active layer pattern of the switching transistor is connected to the corresponding signal reading line through a corresponding first circuit connection pattern, and an orthographic projection of the corresponding first circuit connection pattern on the plane, where the second electrode is located, intersects the first edge; and
a part, which serves as the second pole of the switching transistor, of the source/drain doped region of the active layer pattern of the switching transistor is connected to the first electrode of the photoelectric conversion structure in the same detection pixel unit through a corresponding second circuit connection pattern, and an orthographic projection of the corresponding second circuit connection pattern on the plane, where the second electrode is located, intersects the fourth edge.

14. The photo detection substrate according to claim 4, wherein the signal reading circuit comprises a reset transistor, a source follower transistor, and a selection transistor;
the gate of the reset transistor is connected to a reset control line, a first pole of the reset transistor is connected to a reset voltage supply line, and a second pole of the reset transistor is connected to the first electrode of the photoelectric conversion structure;
the gate of the source follower transistor is connected to the first electrode of the photoelectric conversion structure, a first pole of the source follower transistor is connected to an operating voltage supply line, and a second pole of the source follower transistor is connected to a first pole of the selection transistor;
the gate of the selection transistor is connected to the corresponding gate line, and a second pole of the selection transistor is connected to the corresponding signal reading line.

15. The photo detection substrate according to claim 14, wherein the reset transistor, the source follower transistor, and the selection transistor each are the superposed transistor,
wherein the second electrode has a first edge, a second edge, a third edge, and a fourth edge, the first edge and the second edge are opposite to each other in the second direction, the third edge and the fourth edge are opposite to each other in the first direction;
the second electrode comprises a first sub-region and a second sub-region arranged in the second direction, the channel region of the source follower transistor is in the first sub-region, both of the channel region of the reset transistor and the channel region of the selection transistor are in the second sub-region; and
an orthographic projection of the gate of the source follower transistor on a plane where the second electrode is located, intersects the third edge, an orthographic projection of the gate of the reset transistor on the plane, where the second electrode is located, intersects the second edge, and an orthographic projection of the gate of the selection transistor on the plane, where the second electrode is located, intersects the fourth edge.

16. (canceled)

17. The photo detection substrate according to claim 15, wherein the reset control line, the bias voltage supply line, the gate line, and the first electrode are arranged in the same layer, and the reset control line and the bias voltage supply line each extend in a second direction;
one of the bias voltage supply line corresponding to the detection pixel unit and the reset control line corresponding to the detection pixel unit is on a side closer to the third edge of the second electrode in the detection pixel unit, and the other of the bias voltage supply line and the reset control line is on a side closer to the fourth edge of the second electrode in the detection pixel unit;
the gate line corresponding to the detection pixel unit is on a side closer to the fourth edge of the second electrode in the detection pixel unit; and
a part of the first electrode of the photoelectric conversion structure, which is in contact with the gate of the source follower transistor, is on a side closer to the third edge of the second electrode in the detection pixel unit.

18. The photo detection substrate according to claim 15, further comprising:
a wiring layer on a side of the superposed transistor away from the base substrate, wherein the wiring layer comprises the reset voltage supply line, the operating voltage supply line, and the signal reading line, and the reset voltage supply line and the operating voltage supply line each extend in the first direction;
the operating voltage supply line corresponding to the detection pixel unit is on a side closer to the first edge of the second electrode in the detection pixel unit; and
the reset voltage supply line and the signal reading line corresponding to the detection pixel unit are on a side closer to the second edge of the second electrode in the detection pixel unit.

19. The photo detection substrate according to claim 18, further comprising:
a circuit connection pattern layer between the superposed transistor and the wiring layer, wherein the circuit connection pattern layer comprises a first circuit connection pattern, a second circuit connection pattern, a third circuit connection pattern, and a fourth circuit connection pattern;
a part, which serves as the second pole of the selection transistor, of the source/drain doped region of the active layer pattern of the selection transistor is connected to the corresponding signal reading line through a corresponding first circuit connection pattern, and an orthographic projection of the corresponding first circuit connection pattern on the plane, where the second electrode is located, intersects the second edge;
a part, which serves as the first pole of the reset transistor, of the source/drain doped region of the active layer pattern of the reset transistor is connected to the first electrode of the photoelectric conversion structure through a corresponding second circuit connection pattern, and an orthographic projection of the second circuit connection pattern on the plane, where the second electrode is located, intersects the third edge;
a part, which serves as the second pole of the reset transistor, of the source/drain doped region of the active layer pattern of the reset transistor is connected to the corresponding reset voltage supply line through a corresponding third circuit connection pattern, and an orthographic projection of the corresponding third circuit connection pattern on the plane, where the second electrode is located, intersects the second edge; and
a part, which serves as the first pole of the source follower transistor, of the source/drain doped region of the active layer pattern of the source follower transistor is connected to the corresponding operating voltage supply line through a corresponding fourth circuit connection pattern, and an orthographic projection of the corresponding fourth circuit connection pattern on the plane, where the second electrode is located, intersects the first edge.

20. The photo detection substrate according to claim 14, wherein the source follower transistor is the superposed transistor,
wherein the gate of the reset transistor is in the same layer as the gate of the source follower transistor, and the gate of the selection transistor is in the same layer as the gate of the source follower transistor;
the active layer pattern of the reset transistor is in the same layer as the active layer pattern of the source follower transistor, and an orthographic projection of the active layer pattern of the reset transistor on the base substrate does not overlap with the orthographic projection of the photoelectric conversion structure in the same detection pixel unit on the base substrate; and
the active layer pattern of the selection transistor is in the same layer as the active layer pattern of the source follower transistor, and an orthographic projection of the active layer pattern of the selection transistor on the base substrate does not overlap with the orthographic projection of the photoelectric conversion structure in the same detection pixel unit on the base substrate.

21. (canceled)

22. The photo detection substrate according to claim 14, wherein both of the reset transistor and the selection transistor are the superposed transistors; and
the source follower transistor is between the photoelectric conversion structure and the base substrate,
wherein a material of the active layer pattern of the source follower transistor comprises amorphous silicon or polysilicon,
an orthographic projection of the channel region of the active layer pattern of the source follower transistor on the base substrate is within the orthographic projection of the photoelectric conversion structure in the same detection pixel unit on the base substrate; and
an orthographic projection of at least a part of the source/drain doped region of the active layer pattern of the source follower transistor on the base substrate is outside the orthographic projection of the photoelectric conversion structure in the same detection pixel unit on the base substrate.

23-24. (canceled)

25. An image sensor, comprising the photo detection substrate according to claim 1.

26. An electronic apparatus, comprising the image sensor according to claim 25.
